(19) United States
(12) Patent Application Publication
(10) Pub. No.: US 2026/0095205 A1
(43) Pub. Date: Apr. 2, 2026

(54) SINGLE WIRE SERIAL INTERFACE AND PROTOCOL FOR INTRA-CHIP COMMUNICATIONS

(71) Applicant: STMicroelectronics International N.V., Geneva (CH)

(72) Inventors: Ankur BAL, Greater Noida (IN); Rupesh SINGH, Ghaziabad (IN); Parisha ARORA, Rajpura (IN)

(73) Assignee: STMicroelectronics International N.V., Geneva (CH)

(21) Appl. No.: 19/327,369

(22) Filed: Sep. 12, 2025

Related U.S. Application Data
(60) Provisional application No. 63/699,912, filed on Sep. 27, 2024.

(51) Int. Cl. H04B 3/03; H03K 3/037; H04B 1/18

(52) U.S. Cl. CPC H04B 3/03; H03K 3/037; H04B 1/18

(57) ABSTRACT

Pulses having a first width and a second width greater than the first width are generated from a clock signal. An encoded data stream transmitted over a single communications wire is generated by: selecting the pulse having the first width for each bit of the transmit serial data stream having a first logic state; and selecting the pulse having the second width for each bit of the transmit serial data stream having a second logic state. Pulses of the received encoded data stream having the second width are then detected. A first flip-flop logic state is toggled in response to each detected pulse having the second width. A second flip-flop latches the first flip-flop logic state in response to each pulse of the encoded data stream. Outputs of the first and second flip-flops are logically combined to generate a receive serial data stream corresponding to the transmit serial data stream.

### CROSS REFERENCE TO RELATED APPLICATIONS

This application claims priority from United States Provisional Application for Patent No. 63/699,912, filed Sep. 27, 2024, the content of which is incorporated herein by reference.

### TECHNICAL FIELD

The present invention generally relates to communications carried out between functional circuits distributed over an integrated circuit chip (i.e., intra-chip communications).

### BACKGROUND

Reference is made to FIG. 1 which shows a block diagram layout for an example integrated circuit (IC) chip 10. The IC chip 10 includes a plurality of clock domains 12 and certain integrated circuitry is provided within each clock domain. For example, clock domain A may include integrated circuitry for data storage such as memory circuits 13, clock domain B may include integrated circuitry for processing such as microprocessor 14 and functional block 15 circuits, and clock domain C may include integrated circuitry for external communications interface such as input/output circuits 16. This distribution of circuitry among the various clock domains is understood to just be an example possibility.

The IC chip 10 may further include a distributed process monitoring circuit comprising a process monitoring block (PMB) master control circuit 20 and a plurality of PMB sensor (or slave) circuits 22(a), 22(b), 22(c), 22(d) and 22(e). The PMB master control circuit 20 functions to monitor and control the PMB sensor circuits 22. The PMB master control circuit 20 is further responsible for programming the PMB sensor circuits 22 and collecting and processing the data sensed by the PMB sensor circuits 22.

The circuits 20, 22(a), 22(b), 22(c), 22(d) and 22(e) are interconnected for communication by a multi-wire communications bus 24. Data transfers between the PMB master control circuit 20 and the plurality of PMB sensor circuits 22 occur asynchronously, as the PMB sensor circuits 22 are distributed across the IC chip 10 and are located in different clock domains 12. For asynchronous data transfer, the multi-wire communications bus 24 must support multiple signals (for example, request, acknowledge, enable, control, data, etc.).

The process monitoring circuit may function, for example, to perform process, voltage and temperature (PVT) monitoring of the integrated circuit operation. Such monitoring is critical to achieving reliable operation and optimum performance. This processing monitoring functionality can also be used at electrical wafer sort (EWS) to check that the integrated circuits remain within pre-defined process limits. The processing monitoring functionality can further be used at the application level during product lifetime for temperature monitoring, compensation, debugging and failure analysis.

In a case where the IC chip 10 is a System-on-Chip (SoC) type circuit, there can be hundreds of PMB sensor circuits 22 distributed across the chip area. Interconnecting those circuits 22 to the PMB master control circuit 20 with bus 24 can create routing (wire) congestion issues and routing of the bus lines consumes a not insignificant amount of die area. There is also a significant power consumption associated with operating (for example, driving and switching) those bus communications.

There is accordingly a need in the art for a more efficient means of supporting intra-chip communications. In particular, there is a need for a more efficient means of supporting communications between the PMB master control circuit 20 and the PMB sensor circuits 22 which are distributed across multiple clock domains 12.

### SUMMARY

In an embodiment, a communications system comprises: a transmitter circuit having an output; a receive circuit having an input; and a single communications wire connecting the transmitter circuit output and the receiver circuit input.

The transmitter circuit comprises: a first delay line having an input configured to receive a first clock signal; a second delay line having an input configured to receive a first delayed first clock signal output from the first delay line; a first logic gate configured to logically combine the first clock signal and the first delayed first clock signal; a second logic gate configured to logically combine the first clock signal and a second delayed first clock signal output from the second delay line; and a first multiplexer having a first input coupled to receive an output of the first logic gate and a second input coupled to receive an output of the second logic gate, wherein a selection control input of the first multiplexer receives a transmit serial data stream, and wherein an output of the first multiplexer generates an encoded data stream applied at the output of the transmitter circuit to the single communications wire.

The receiver circuit comprises: a third delay line having an input configured to receive the encoded data stream; a third logic gate configured to logically combine the encoded data stream with a delayed encoded data stream output from the third delay line; a first flip-flop configured as a toggle and having a clock input coupled to receive an output of the third logic gate; a second flip-flip having an input coupled to an output of the first flip-flop and having a clock input coupled to receive the encoded data stream; and a fourth logic gate configured to logically combine the output of the first flip-flop and an output of the second flip-flop to generate a receive serial data stream corresponding to the transmit serial data stream.

In an embodiment, a transmitter circuit is configured to receive a transmit serial data stream and encode the transmit serial data stream generate an encoded data stream for transmission over a single communications wire. The transmitter circuit comprises: a first delay line having an input configured to receive a clock signal; a second delay line having an input configured to receive a first delayed clock signal output from the first delay line; a first logic gate configured to logically combine the clock signal and the first delayed clock signal; a second logic gate configured to logically combine the clock signal and a second delayed clock signal output from the second delay line; and a first multiplexer having a first input coupled to receive an output of the first logic gate and a second input coupled to receive an output of the second logic gate, wherein a selection control input of the first multiplexer receives the transmit serial data stream, and wherein an output of the first multiplexer generates the encoded data stream.

In an embodiment, a receiver circuit is configured to receive an encoded data stream generated from a transmit serial data stream and decode the encoded data stream to generate a receive serial data stream. The receiver circuit comprises: a delay line having an input configured to receive the encoded data stream; a first logic gate configured to logically combine the encoded data stream with a delayed encoded data stream output from the delay line; a first flip-flop configured as a toggle and having a clock input coupled to receive an output of the first logic gate; a second flip-flip having an input coupled to an output of the first flip-flop and having a clock input coupled to receive the encoded data stream; and a second logic gate configured to logically combine the output of the first flip-flop and an output of the second flip-flop to generate the receive serial data stream corresponding to the transmit serial data stream.

In an embodiment, a method comprises: receiving a transmit serial data stream; generating from a clock signal a pulse having a first width; generating from the clock signal a pulse having a second width greater than the first width; output an encoded data stream for transmission over a single communications wire by: selecting the pulse having the first width in response to each bit of the transmit serial data stream having a first logic state; and selecting the pulse having the second width in response to each bit of the transmit serial data stream having a second logic state different from the first logic state.

The method further comprises: receiving the encoded data stream transmitted over the single communications wire; detecting pulses of the encoded data stream having the second width; toggling a first flip-flop logic state in response to each detected pulse having the second width; latching in a second flip-flop the first flip-flop logic state in response to each first width and second width pulse of the encoded data stream; and logically combining logic states at outputs of the first and second flip-flops to generate a receive serial data stream corresponding to the transmit serial data stream.

### BRIEF DESCRIPTION OF THE DRAWINGS

For a better understanding of the embodiments, reference will now be made by way of example only to the accompanying figures in which:

FIG. 1 shows a block diagram layout for an example integrated circuit (IC) chip;

FIG. 2 shows a block diagram for distributed process monitoring circuit according to an embodiment herein; and

FIGS. 3A and 3B show, respectively, a circuit diagram for a transmitter circuit of a PMB master control circuit in the distributed process monitoring circuit of FIG. 2 and a timing diagram illustrating operation of the transmitter circuit;

FIGS. 4A and 4B show, respectively, a circuit diagram for a receiver circuit of the PMB master control circuit in the distributed process monitoring circuit of FIG. 2 and a timing diagram illustrating operation of the receiver circuit; and

FIG. 5 shows a circuit diagram for a transceiver circuit of a PMB sensor circuit in the distributed process monitoring circuit of FIG. 2.

### DETAILED DESCRIPTION

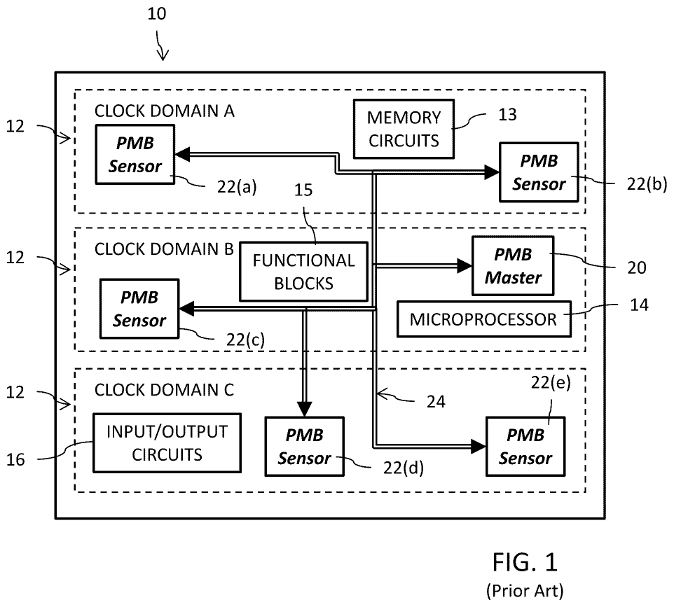

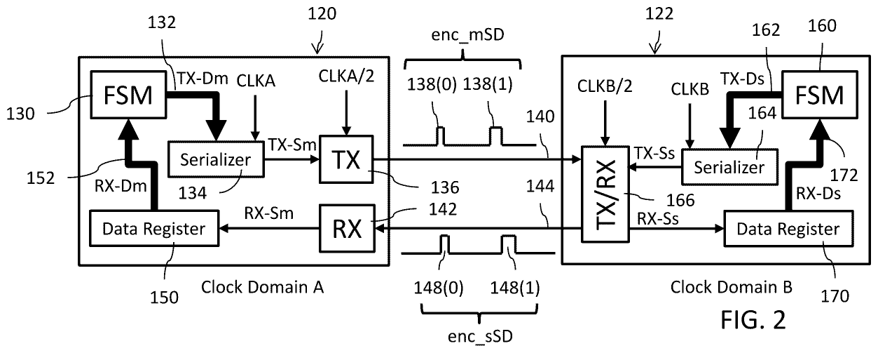

Reference is now made to FIG. 2 which shows a block diagram for a distributed process monitoring circuit according to an embodiment herein. The illustration of FIG. 2 is simplified in that it shows only two components of the distributed process monitoring circuit: a process monitoring block (PMB) master control circuit 120 and a single PMB sensor circuit 122 connected for communication over a first single wire serial data line 140 (for handling communications from the PMB master control circuit 120 to the PMB sensor circuit 122) and a second single wire serial data line 144 (for handling communications from the PMB sensor circuit 122 to the PMB master control circuit 120). Those skilled in the art understand that the distributed process monitoring circuit may include tens or hundreds of PMB sensor circuits 122 connected for communication with the PMB master control circuit 120. The example illustrated in FIG. 2 thus can be expanded to include as many PMB sensor circuits connected to the PMB master control circuit 120 as necessary for a given integrated circuit chip 10 application. A separate pair of single wire serial data lines 140, 144 would be used for PMB master control circuit 120 connection to each PMB sensor circuit 122. The collection of pairs of single wire serial data lines 140, 144 interconnecting the PMB sensor circuit 122 and the plurality of PMB sensor circuits 122 would be used in place of the bus 24 shown in FIG. 1.

The PMB master control circuit 120 includes a finite state machine (FSM) control circuit 130 configured to generate master transmit data (TX-Dm), for example as a transmit data word of 16 or 32 bits in width, on a multi-wire parallel bus 132 for communication to the PMB sensor circuit 122. This master transmit data TX-Dm may, for example, comprise data used for programming the PMB sensor circuit 122 or data used for controlling operation and/or configuration of the PMB sensor circuit 122. A serializer circuit 134 receives a clock signal CLKA for the clock domain within which the PMB master control circuit 120 is located and serializes the master transmit data TX-Dm data word to generate a master serial transmit data stream TX-Sm synchronized to the clock signal CLKA with one data bit per clock period. A transmitter circuit 136 receives a divided by two clock signal CLKA/2 for the clock domain and encodes the data bits of the master serial transmit data stream TX-Sm as an encoded master serial data transmission (enc_mSD) including signal pulses 138 of data bit logic state dependent width for transmission to the PMB sensor circuit 122 over the first single wire serial data line 140. For example, a data bit of the master serial transmit data stream TX-Sm having a first logic state (for example, a logic 0 state) is encoded by the transmitter circuit 136 as a (positive) signal pulse 138(0) in the encoded master serial data transmission enc_mSD on serial data line 140 having a first pulse width (which is dependent on a circuit first time delay explained in detail herein), and a data bit of the master serial transmit data stream TX-Sm having a second logic state (for example, a logic 1 state) is encoded by the transmitter circuit 136 as a (positive) signal pulse 138(1) in the encoded master serial data transmission enc_mSD on serial data line 140 having a second pulse width (which is longer than the first pulse width and which is dependent on a circuit second time delay explained in detail herein). The signal pulses are periodically transmitted in a serial stream of the encoded master serial data transmission enc_mSD with a frequency equal to a frequency of the clock signal CLKA. Thus, the period of signal transmission on the single wire serial data line 140 is equal to the period of the clock signal CLKA.

A receiver circuit 142 of the PMB master control circuit 120 receives an encoded sensor serial data (enc_sSD) transmission from the PMB sensor circuit 122 on the second single wire serial data line 144. This encoded serial data, similar to the serial data transmitted on first single wire serial data line 140, has a signal period with signal pulses 148 of variable width dependent on data bit logic state and the clock period of the clock signal CLKB for the clock domain within which the PMB sensor circuit 122 is located. A (positive) signal pulse 148(0) having a third pulse width (which is dependent on a circuit third time delay explained in detail herein) encodes a PMB sensor circuit 122 transmitted data bit having a first logic state (for example, a logic 0 state), and a (positive) signal pulse 148(1) having a fourth pulse width (which is longer than the third pulse width and which is dependent on a circuit fourth time delay explained in detail herein) encodes a PMB sensor circuit 122 transmitted data bit having a second logic state (for example, a logic 1 state). The receiver circuit 142 decodes the signal pulses 148 of the encoded sensor serial data transmission enc_sSD to generate a master serial receive data stream RX-Sm and the data bits of that master serial receive data stream RX-Sm are stored in a data register circuit 150. The FSM control circuit 130 periodically retrieves the master receive data (RX-Dm) from the data bits stored in the data register circuit 150 over a multi-wire parallel bus 152 as a receive data word of 16 or 32 bits in width.

The PMB sensor circuit 122 includes a finite state machine (FSM) control circuit 160 configured to generate sensor transmit data (TX-Ds), for example as a transmit data word of 16 or 32 bits in width, on a multi-wire parallel bus 162 for communication to the PMB sensor circuit 122. This sensor transmit data TX-Ds may, for example, comprise data used for communicating process monitored information sensed by the PMB sensor circuit 122. A serializer circuit 164 receives a clock signal CLKB for the clock domain within which the PMB sensor circuit 122 is located and serializes the sensor transmit data TX-Ds data word to generate a sensor serial transmit data stream TX-Ss synchronized to the clock signal CLKB with one data bit per clock period. A transceiver circuit 166 receives a divided by two clock signal CLKB/2 for the clock domain and encodes the data bits of the sensor serial transmit data stream TX-Ss as signal pulses 148 of data bit logic state dependent width for transmission to the PMB master control circuit 120 over the second single wire serial data line 144. For example, a data bit of the sensor serial transmit data stream TX-Ss having a first logic state (for example, a logic 0 state) is encoded by the transceiver circuit 166 as a (positive) signal pulse 148(0) in the encoded sensor serial data transmission enc_sSD on serial data line 144 having the third pulse width (which is dependent on a circuit third time delay explained in detail herein), and a data bit of the sensor serial transmit data stream TX-Ss having a second logic state (for example, a logic 1 state) is encoded by the transceiver circuit 166 as a (positive) signal pulse 148(1) in the encoded sensor serial data transmission enc_sSD on serial data line 144 having the fourth pulse width (which is longer than the third pulse width and which is dependent on a circuit fourth time delay explained in detail herein). The signal pulses are periodically transmitted in a serial stream of the encoded sensor serial data transmission enc_sSD with a frequency equal to a frequency of the clock signal CLKB. Thus, the period of signal transmission on the single wire serial data line 144 is equal to the period of the clock signal CLKB.

The transceiver circuit 166 also receives the encoded master serial data transmission enc_mSD from the PMB master control circuit 120 on the first single wire serial data line 140. This encoded serial data, as discussed above, has a signal period with signal pulses 138 of data bit logic state dependent width dependent on the circuit first and second time delays. A (positive) signal pulse 138(0) having the first pulse width (which is dependent on a circuit first time delay explained in detail herein) encodes a PMB master control circuit 120 transmitted data bit having a first logic state (for example, a logic 0 state), and a (positive) signal pulse 138(1) having the second pulse width (which is longer than the first pulse width and which is dependent on a circuit second time delay explained in detail herein) encodes a PMB master control circuit 120 transmitted data bit having a second logic state (for example, a logic 1 state). The transceiver circuit 166 decodes the signal pulses 138 of the encoded master serial data transmission enc_mSD to generate a sensor serial receive data stream RX-Ss and the data bits of that sensor serial receive data stream RX-Ss are stored in a data register circuit 170. The FSM control circuit 160 periodically retrieves the sensor receive data (RX-Ds) from the data bits stored in the data register circuit 170 over a multi-wire parallel bus 172 as a receive data word of 16 or 32 bits in width.

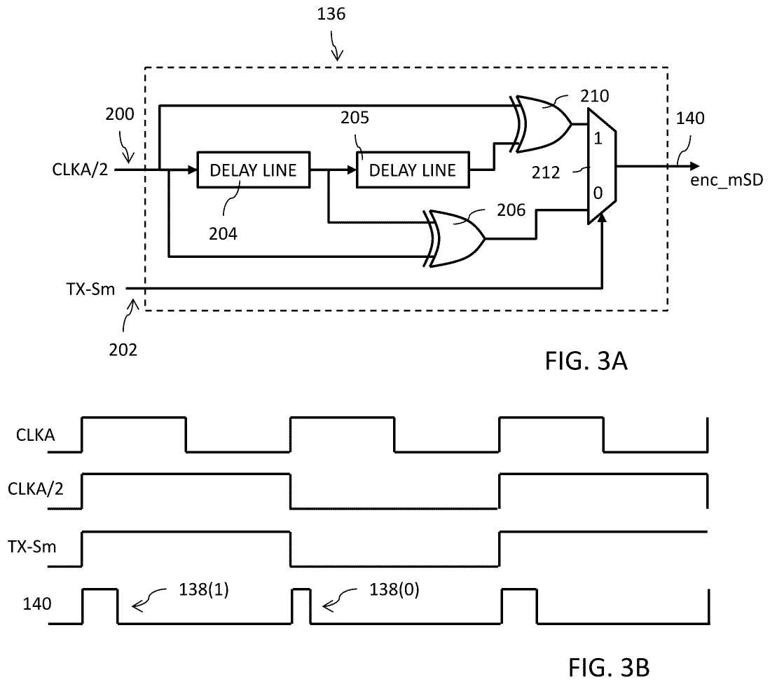

Reference is now made to FIGS. 3A and 3B. FIG. 3A is a circuit diagram for the transmitter circuit 136 of the PMB master control circuit 120. FIG. 3B is a timing diagram illustrating operation of the transmitter circuit 136 for encoding the data bits of the master serial transmit data stream TX-Sm as signal pulses 138 of the encoded master serial data for transmission enc_mSD over the first single wire serial data line 140. The transmitter circuit 136 includes an input 200 configured to receive the divided by two clock signal CLKA/2 for the clock domain A where the PMB master control circuit 120 is located and an input 202 configured to receive the master serial transmit data stream TX-Sm (output from the serializer 134). The divided by two clock signal CLKA/2 is applied to the input of a first delay line 204 that is configured to apply a first time delay td1 (corresponding to the circuit first time delay noted above). The divided by two clock signal CLKA/2 (from input 200) and the divided by two clock signal CLKA/2 delayed by td1 (at the output of first delay line 204) are applied as inputs to a first logical combination circuit 206 (here implemented as a logical exclusive OR (XOR) gate). The signal generated at the output of the first logical combination circuit 206 is the pulse 138(0) having the first pulse width which equals the first time delay td1. The output of first delay line 204 is connected to the input of a second delay line 205 which is configured to apply a second time delay td2. In an embodiment, td1=td2, but this is not necessarily a requirement. The divided by two clock signal CLKA/2 (from input 200) and the divided by two clock signal CLKA/2 delayed by td1+td2 at the output of second delay line 205 are applied as inputs to a second logical combination circuit 210 (here implemented as a logical exclusive OR (XOR) gate). The signal generated at the output of the second logical combination circuit 210 is the pulse 138(1) having the second pulse width which equals the sum of the first time delay td1 and the second time delay td2 (corresponding to the circuit second time delay noted above). The signal generated at the output of the first logical combination circuit 206 is applied to a first (logic 0 select) input of a multiplexer circuit 212, and the signal generated at the output of the second logical combination circuit 210 is applied to a second (logic 1 select) input of the multiplexer circuit 212. The control (selection) input of multiplexer circuit 212 receives the master serial transmit data stream TX-Sm signal from the second input 202. When a current bit of the master serial transmit data stream TX-Sm signal has a logic 0 state, the multiplexer circuit 212 selects the pulse 138(0) signal (having the first pulse width) generated at the output of the first logical combination circuit 206 for transmission on the first single wire serial data line 140 as a pulse of the encoded master serial data transmission enc_mSD. Conversely, when a current bit of the master serial transmit data stream TX-Sm has a logic 1 state, the multiplexer circuit 212 selects the pulse 138(1) signal (having the second pulse width) generated at the output of the second logical combination circuit 210 for transmission on the first single wire serial data line 140 as a pulse of the encoded master serial data transmission enc_mSD.

The timing diagram of FIG. 3B shows the following signals: CLKA—the clock signal for the clock domain A; CLKA/2—the divided by two clock signal for the clock domain A; TX—Sm—the master serial transmit data stream signal; and 140—the encoded master serial data signal enc_mSD transmitted on the first single wire serial data line 140.

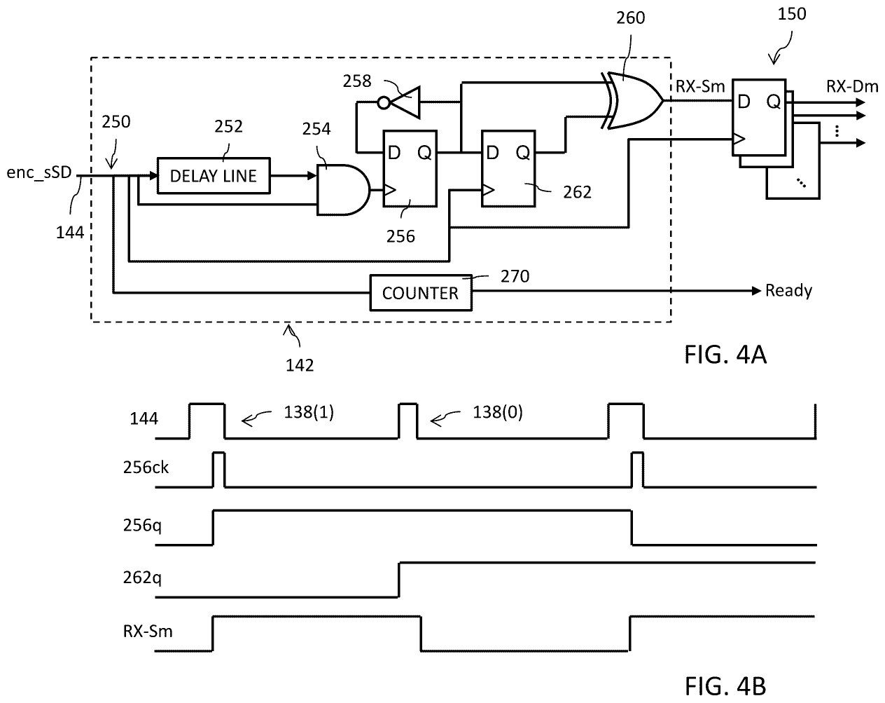

Reference is now made to FIGS. 4A and 4B. FIG. 4A is a circuit diagram for the receiver circuit 142 of the PMB master control circuit 120. FIG. 4B is a timing diagram illustrating operation of the receiver circuit 142 for decoding the data bits of the encoded serial data transmitted by the PMB sensor circuit 122 on the second single wire serial data line 144. An input 250 of the receiver circuit 142 is connected to the second single wire serial data line 144. The encoded sensor serial data transmission enc_sSD on line 144 received at input 250 is applied to the input of a third delay line 252 which is configured to apply a third time delay td3. In an embodiment, td3=1.5*td1 (where td1=td2 as noted above), and thus the third time delay td3 is between the time delays provided by the circuit third and fourth time delays of the PMB sensor circuit 122 noted above. The encoded sensor serial data signal enc_sSD (received at input 250) and the encoded sensor serial data signal enc_sSD delayed by td3 (at the output of third delay line 252) are applied as inputs to a third logical combination circuit 254 (here implemented as a logical AND gate). The signal generated at the output of the third logical combination circuit 254 is applied to the clock input of a first flip-flop circuit 256 (here implemented as a D-type flip-flop). The signal generated at the data output (Q) of the first flip-flop circuit 256 is inverted by logic inverter 258 and applied to the input (D) of the first flip-flop circuit 256. The signal generated at the data output (Q) of the first flip-flop circuit 256 is further applied to a first input of a fourth logical combination circuit 260 (here implemented as a logical exclusive OR (XOR) gate) and to the input (D) of a second flip-flop circuit 262. The signal generated at the data output (Q) of the second flip-flop circuit 262 is applied to a second input of the fourth logical combination circuit 260. The encoded sensor serial data signal enc_sSD (received at input 250) is further applied to the clock input of the second flip-flop circuit 262. The signal generated at the output of the fourth logical combination circuit 260 is the master serial receive data stream RX-Sm signal decoded from the encoded sensor serial data transmission enc_sSD on line 144. This RX-Sm signal is applied to the flip-flop circuits making up the register 150.

The timing diagram of FIG. 4B shows the following signals: 144—the encoded sensor serial data signal enc_sSD received on second single wire serial data line 144; 256ck—the output of AND gate 254 at the clock input of flip-flop 256; 256q—the data (Q) output of flip-flip 256; 262q—the data (Q) output of flip-flop 262; and RX-Sm—the master serial receive data stream signal at the output of XOR gate 260.

The receiver circuit 142 of the PMB master control circuit 120 operates as follows to perform the decoding operation. The delay line 252 and the AND gate 254 function to detect receipt of the pulse 138(1) having the second width. When detected, as shown by the pulse of signal 256ck, the first flip-flop 256, configured to operate as a toggle, is clocked and changes state, as shown by signal 256q. The second flip-flop 262 was previously latched by the pulse 138(1) to save the opposite logic state. The XOR gate 260 output then changes to the logic high state presenting the decoded logic 1 bit value of the pulse 138(1). In response to receipt of the pulse 138(0) having the first width (less than the second width), the first width is not sufficiently long enough for the delay line 252 and the AND gate 254 to detect the pulse. There is accordingly no toggling of the first flip-flop 256 which continues to hold its previous state. However, the second flip-flop 262 is triggered by the pulse 138(0) to latch the logic state at the output of the first flip-flop 256, as shown by signal 262q. Now, flip-flops 256 and 262 save the same logic state, the XOR gate 260 output then changes to the logic low state presenting the decoded logic 0 bit value of the pulse 138(0).

It will be noted that the receiver circuit 142 does not need or receive either of the clock signals CLKA or CLKB to perform the decoding operation.

FIG. 4A further shows a counter circuit 270 having an input configured to receive the encoded sensor serial data signal enc_sSD (from input 250). The counter 270 counts pulses 148 of the encoded sensor serial data signal enc_sSD and a ready signal (Ready) is asserted when the count value in the counter 270 reaches a certain value (at which point, the counter 270 is reset). This certain value corresponds to a number of bits in the master receive data (RX-Dm) data word. In response to the periodic assertion of the Ready signal, the FSM 130 knows that it is time to read the bits of the master receive data (RX-Dm) from the data register 150 to output the receive data word.

FIG. 4A also shows an example implementation of the data register 150 as a set of flip-flops connected in serial shift register fashion to receive the decoded bits of the master serial receive data stream RX-Sm signal from the output of the fourth logical combination circuit 260. The flip-flops of the data register 150 are clocked by the encoded sensor serial data signal enc_sSD (from input 250). The parallel output from the flip-flops of the data register 150 provides the master receive data RX-Dm data word.

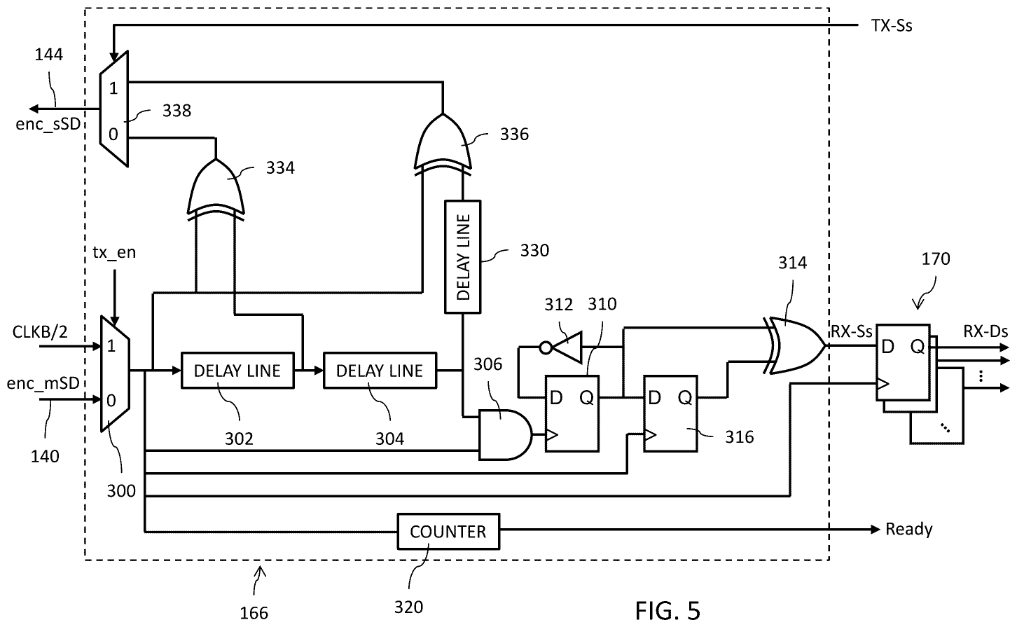

Reference is now made to FIG. 5 which shows a circuit diagram for the transceiver circuit 166 of the PMB sensor circuit 122. A first (logic 0 select) input of a multiplexer circuit 300 receives the encoded master serial data signal enc_mSD on the first single wire serial data line 140. A second (logic 1 select) input of the multiplexer circuit 300 receives a divided by two clock signal CLKB/2 for the clock domain within which the PMB sensor circuit 122 is located. The control (selection) input of the multiplexer circuit 300 receives a transmit enable signal (tx_en) generated by the FSM 160, where this signal tx_en is indicative of whether the transceiver circuit 166 is currently operating in transmit mode or receive mode. When the transmit enable signal tx_en has a logic 0 state, indicating that the transceiver circuit 166 is currently operating in receive mode, the multiplexer circuit 300 selects the received encoded master serial data signal enc_mSD (transmitted by PMB master control circuit 120 on the first single wire serial data line 140) for output. Conversely, when the transmit enable signal tx_en has a logic 1 state, indicating that the transceiver circuit 166 is currently operating in transmit mode, the multiplexer circuit 300 selects the divided by two clock signal CLKB/2 of the clock domain B for the PMS sensor circuit 122 for output.

For receive operation when the transmit enable signal tx_en has the logic 0 state, the encoded master serial data signal enc_mSD selected by the multiplexer circuit 300 is applied to the input of a fourth delay line 302 which is configured to apply a fourth time delay td4. In an embodiment, td4=td1 (where td1=td2). The output of the fourth delay line 302 is connected to the input of a fifth delay line 304 which is configured to apply a fifth time delay td5. In an embodiment, td5=td4/2. The encoded master serial data signal enc_mSD (at the output of multiplexer circuit 300) and the encoded master serial data signal enc_mSD delayed by td4+td5 (at the output of fifth delay line 304) are applied as inputs to a fifth logical combination circuit 306 (here implemented as a logical AND gate). The sum of the fourth and fifth time delays td4, td5 is between the time delays provided by the circuit first and second time delays of the PMB master control circuit 120 as noted above. The signal generated at the output of the fifth logical combination circuit 306 is applied to the clock input of a third flip-flop circuit 310 (here implemented as a D-type flip-flop). The signal generated at the data output (Q) of the third flip-flop circuit 310 is inverted by logic inverter 312 and applied to the input (D) of the third flip-flop circuit 310. The signal generated at the data output (Q) of the third flip-flop circuit 310 is further applied to a first input of a sixth logical combination circuit 314 (here implemented as a logical exclusive OR (XOR) gate) and to the input (D) of a fourth flip-flop circuit 316. The signal generated at the data output (Q) of the fourth flip-flop circuit 316 is applied to a second input of the sixth logical combination circuit 314. The encoded master serial data signal enc_mSD (selected by multiplexer 300) is further applied to the clock input of the fourth flip-flop circuit 316. The signal generated at the output of the sixth logical combination circuit 314 is the sensor serial receive data stream RX-Ss signal decoded from the encoded master serial data transmission enc_mSD on line 140. This RX-Ss signal is applied to the flip-flop circuits forming the register 170.

A timing diagram for operation of the transceiver 166 when configured by the transmit enable signal tx_en in receive mode generally corresponds to the timing diagram shown by FIG. 4B for the receiver 142.

The operation of the receive portion of the transceiver circuit 166 of the PMB sensor circuit 122 is like the operation previously described for the receiver circuit 142 of FIG. 4A.

It will be noted that the receive portion of the transceiver circuit 166 does not need or receive either of the clock signals CLKA or CLKB to perform the decoding operation.

FIG. 5 further shows a counter circuit 320 having an input configured to receive the encoded master serial data signal enc_mSD (selected by multiplexer 300). The counter 320 counts pulses 144 of the encoded master serial data signal enc_mSD and a ready signal (Ready) is asserted when the count value in the counter 320 reaches a certain value. This certain value corresponds to a number of bits in the sensor receive data (RX-Ds) data word. In response to periodic assertion of the Ready signal, the FSM 160 knows that it is time to read the bits of the sensor receive data (RX-Ds) from the data register 170 and output the receive data word.

FIG. 5 also shows an example implementation of the data register 170 as a series of flip-flops connected in serial fashion to receive the decoded bits of the sensor serial receive data stream RX-Ss signal from the output of the sixth logical combination circuit 314. The flip-flops of the data register 170 are clocked by the encoded master serial data signal enc_mSD (selected by multiplexer 300). The parallel output from the flip-flops of the data register 170 provides the sensor receive data RX-Ds.

For transmit operation when the transmit enable signal tx_en has the logic 1 state, the divided by two clock signal CLKB/2 selected by the multiplexer circuit 300 is applied to the input of the fourth delay line 302 which is configured to apply the fourth time delay td4. The output of the fourth delay line 302 is connected to the input of the fifth delay line 304 which is configured to apply the fifth time delay td5. The output of fifth delay line 304 is connected to the input of a sixth delay line 330 which is configured to apply a sixth time delay td6. In an embodiment, td6=td5=td4/2. The divided by two clock signal CLKB/2 (selected by multiplexer 300) and the divided by two clock signal CLKB/2 delayed by td4 (at the output of fourth delay line 302) are applied as inputs to a seventh logical combination circuit 334 (here implemented as a logical exclusive OR (XOR) gate). The signal generated at the output of the seventh logical combination circuit 334 is the pulse 148(0) having the third pulse width which equals the fourth time delay td4 (corresponding to the circuit third delay noted above). The divided by two clock signal CLKB/2 (selected by multiplexer 300) and the divided by two clock signal CLKB/2 delayed by td4+td5+td6 (at the output of sixth delay line 330) are applied as inputs to an eighth logical combination circuit 336 (here implemented as a logical exclusive OR (XOR) gate). The signal generated at the output of the eighth logical combination circuit 336 is the pulse 148(2) having the fourth pulse width which equals the sum of the fourth time delay td1, the fifth time delay td5, and the sixth delay time td6 (corresponding to the circuit fourth delay time noted above). The signal generated at the output of the seventh logical combination circuit 334 is applied to a first (logic 0 select) input of a multiplexer circuit 338, and the signal generated at the output of the eighth logical combination circuit 336 is applied to a second (logic 1 select) input of the multiplexer circuit 338. The control (selection) input of multiplexer circuit 338 receives the sensor serial transmit data stream TX-Ss. When a current bit of the sensor serial transmit data stream TX-Ss has a logic 0 state, the multiplexer circuit 338 selects the pulse 148(0) signal (having the third pulse width) generated at the output of the seventh logical combination circuit 334 for transmission on the second single wire serial data line 144 as a pulse of the encoded sensor serial data transmission enc_sSD. Conversely, when a current bit of the sensor serial transmit data stream TX-Sm has a logic 1 state, the multiplexer circuit 338 selects the pulse 148(1) signal (having the second pulse width) generated at the output of the eighth logical combination circuit 336 for transmission on the second single wire serial data line 144 as a pulse of the encoded sensor serial data transmission enc_sSD.

A timing diagram for operation of the transceiver 166 when configured by the transmit enable signal tx_en in transmit mode generally corresponds to the timing diagram shown by FIG. 3B for the transmitted 136.

As an alternative to use of the transceiver circuit 166 in the PMB sensor circuit 122, the transmitter 136 and receiver 142 circuits, as shown in FIGS. 3A and 4A, could instead be used.

Advantages of the implementation shown in FIGS. 2, 3A, 4A and 5 over the implementation of the prior art shown in FIG. 1 include: use of only one wire per transmitter, providing enhanced usefulness for heterogeneous integration; ease of routing congestion when many sensors are included in one chip; data transmission, in either direction, is asynchronous and independent of the specific clock domain of the transmitter and receiver; there is a mitigation of request, acknowledge and control signaling need; data transmission time is reduced; and there is a significant savings in routing area and power consumption.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A communications system, comprising:
a transmitter circuit having an output;
a receive circuit having an input; and
a single communications wire connecting the transmitter circuit output and the receiver circuit input;
wherein the transmitter circuit comprises:
a first delay line having an input configured to receive a first clock signal;
a second delay line having an input configured to receive a first delayed first clock signal output from the first delay line;
a first logic gate configured to logically combine the first clock signal and the first delayed first clock signal;
a second logic gate configured to logically combine the first clock signal and a second delayed first clock signal output from the second delay line; and
a first multiplexer having a first input coupled to receive an output of the first logic gate and a second input coupled to receive an output of the second logic gate, wherein a selection control input of the first multiplexer receives a transmit serial data stream, and wherein an output of the first multiplexer generates an encoded data stream applied at the output of the transmitter circuit to the single communications wire; and
wherein the receiver circuit comprises:
a third delay line having an input configured to receive the encoded data stream;
a third logic gate configured to logically combine the encoded data stream with a delayed encoded data stream output from the third delay line;
a first flip-flop configured as a toggle and having a clock input coupled to receive an output of the third logic gate;
a second flip-flip having an input coupled to an output of the first flip-flop and having a clock input coupled to receive the encoded data stream; and
a fourth logic gate configured to logically combine the output of the first flip-flop and an output of the second flip-flop to generate a receive serial data stream corresponding to the transmit serial data stream.

2. The communications system of claim 1, wherein the transmitter circuit and the receiver circuit are in different clock domains.

3. The communications system of claim 1, wherein the first, second and fourth logic gates are XOR gates, and the third logic gate is an AND gate.

4. The communications system of claim 1, wherein the communications system is located on an integrated circuit chip, the transmitter circuit is a component of a process monitoring block (PMB) master control circuit and the receiver circuit is a component of a PMB sensor control circuit.

5. The communications system of claim 1, wherein the communications system is located on an integrated circuit chip, the receiver circuit is a component of a process monitoring block (PMB) master control circuit and the transmitter circuit is a component of a PMB sensor control circuit.

6. The communications system of claim 1, wherein the first and second delay lines apply first and second time delays, respectively, and the third delay line applies a third time delay greater than either of the first and second time delays but less than a sum of the first and second time delays.

7. The communications system of claim 1, wherein the receiver circuit further comprises:
a second multiplexer having a first input coupled to receive the encoded data stream and a second input coupled to receive a second clock signal, wherein a selection control input of the second multiplexer receives a transmit enable signal, and wherein an output of the second multiplexer is coupled to the input of the third delay line.

8. The communications system of claim 7, wherein the transmitter circuit is in a first clock domain having the first clock signal and the receiver circuit is in a second clock domain having the second clock signal.

9. The communications system of claim 7, wherein the transmit enable signal is controlled in a first logic state when the receiver circuit is operating to process the encoded data stream to cause the second multiplexer to select the encoded data stream for output, and controlled in a second logic state when the receiver circuit is operating to transmit to cause the second multiplexer to select the second clock signal.

10. The communications system of claim 9, further comprising:
a fourth delay line having an input coupled to the output of the third delay line;
a fifth logic gate configured to logically combine the second clock signal and a first delayed second clock signal output from the third delay line;
a sixth logic gate configured to logically combine the second clock signal and a second delayed second clock signal output from the fourth delay line; and
a third multiplexer having a first input coupled to receive an output of the fifth logic gate and a second input coupled to receive an output of the sixth logic gate, wherein a selection control input of the third multiplexer receives a further transmit serial data stream, and wherein an output of the third multiplexer generates a further encoded data stream applied at an output of the receiver circuit to a further single communications wire.

11. A transmitter circuit configured to receive a transmit serial data stream and encode the transmit serial data stream generate an encoded data stream for transmission over a single communications wire, comprising:
a first delay line having an input configured to receive a clock signal;
a second delay line having an input configured to receive a first delayed clock signal output from the first delay line;
a first logic gate configured to logically combine the clock signal and the first delayed clock signal;
a second logic gate configured to logically combine the clock signal and a second delayed clock signal output from the second delay line; and
a first multiplexer having a first input coupled to receive an output of the first logic gate and a second input coupled to receive an output of the second logic gate, wherein a selection control input of the first multiplexer receives the transmit serial data stream, and wherein an output of the first multiplexer generates the encoded data stream.

12. A receiver circuit configured to receive an encoded data stream generated from a transmit serial data stream and decode the encoded data stream to generate a receive serial data stream, comprising:
a delay line having an input configured to receive the encoded data stream;
a first logic gate configured to logically combine the encoded data stream with a delayed encoded data stream output from the delay line;
a first flip-flop configured as a toggle and having a clock input coupled to receive an output of the first logic gate;
a second flip-flip having an input coupled to an output of the first flip-flop and having a clock input coupled to receive the encoded data stream; and
a second logic gate configured to logically combine the output of the first flip-flop and an output of the second flip-flop to generate the receive serial data stream corresponding to the transmit serial data stream.

13. A method, comprising:
receiving a transmit serial data stream;
generating from a clock signal a pulse having a first width;
generating from the clock signal a pulse having a second width greater than the first width;
output an encoded data stream for transmission over a single communications wire by:
selecting the pulse having the first width in response to each bit of the transmit serial data stream having a first logic state; and
selecting the pulse having the second width in response to each bit of the transmit serial data stream having a second logic state different from the first logic state.

14. The method of claim 13, wherein the transmit serial data stream is synchronized to the clock signal with one bit per clock period.

15. The method of claim 13, wherein the encoded data stream is synchronized to the clock signal with one pulse per clock period.

16. The method of claim 13, further comprising:
receiving the encoded data stream transmitted over the single communications wire;
detecting pulses of the encoded data stream having the second width;
toggling a first flip-flop logic state in response to each detected pulse having the second width;
latching in a second flip-flop the first flip-flop logic state in response to each first width and second width pulse of the encoded data stream; and
logically combining logic states at outputs of the first and second flip-flops to generate a receive serial data stream corresponding to the transmit serial data stream.
